(19) United States
(12) Patent Application Publication
(10) Pub. No.: US 2010/0108495 A1
(43) Pub. Date: May 6, 2010

(54) THIN FILM FORMATION APPARATUS AND MAGNETIC RECORDING MEDIUM MANUFACTURING METHOD

(75) Inventor: Einstein Noel ABARRA, Hachioji-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/547,259

(22) Filed: Aug. 25, 2009

(30) Foreign Application Priority Data
Oct. 31, 2008 (JP) 2008-282384

(51) Int. Cl. C23C 14/34

(52) U.S. Cl. 204/192.15; 204/298.09

(57) ABSTRACT

The present invention provides a thin film formation apparatus which includes a plurality of chambers, and performs processing for forming thin films on two surfaces of a substrate transferred to the plurality of chambers, wherein a first sputtering chamber of the plurality of chambers includes a first sputtering film formation unit configured to perform a sputtering film formation process on a first surface of the substrate, and a first heating unit configured to heat a second surface opposite to the first surface of the substrate, and a second sputtering chamber of the plurality of chambers includes a second heating unit configured to heat the first surface of the substrate having undergone the sputtering film formation process performed by the first sputtering chamber, and a second sputtering film formation unit configured to perform a sputtering film formation process on the second surface of the substrate heated by the first sputtering chamber.

### BACKGROUND OF THE INVENTION

1. Field of the Invention

The present invention relates to a thin film formation apparatus and magnetic recording medium manufacturing method.

2. Description of the Related Art

Recently, magnetic recording media are being extensively researched and developed as means for recording enormous amounts of information. Presently, a recording method called “perpendicular recording method” that records signals by pointing magnetization vectors in the direction perpendicular to the in-plane direction of a recording layer is being mass produced.

In the magnetic recording media, a Co—Cr-based alloy is mainly used as a recording layer.

The recording layer (magnetic recording film) of the magnetic recording medium is required to have high magnetic anisotropy to maintain thermal stability of written information. Materials having high magnetic anisotropy are expected to be used in thermally assisted magnetic recording where the medium is heated while switching magnetic domains. Heating the medium reduces the coercivity and facilitates bit writing. Bit-patterned media, in which dot patterns are artificially and regularly arranged, need to be formed out of high anisotropy materials as well for thermal stability. Examples of promising materials having high magnetic anisotropy are alloys of Co and Fe such as CoPt, FePt, and CoFePt which require high deposition temperatures to obtain the high anisotropy ordered structures.

To form a recording layer having high magnetic anisotropy, the substrate temperature must be raised and controlled at a predetermined temperature. For example, a thin-film stack manufacturing apparatus disclosed in Japanese Patent Laid-Open No. 2008-176847 includes a plurality of chambers, and a heating means for heating a film formation substrate. The substrate is sequentially transferred into the individual chambers, and a plurality of thin films are stacked on the substrate by sputtering. A plurality of substrates is simultaneously accommodated in the many chambers. While a thin film is being formed on a substrate, the heating means heats another substrate waiting for film deposition.

Unfortunately, the thin-film stack manufacturing apparatus disclosed in Japanese Patent Laid-Open No. 2008-176847 has the problem that uniform temperature control cannot be performed while a film is formed on a film formation substrate (i.e., during film formation). Moreover, after heating, the substrate temperature immediately drops as it is transported for sputtering especially when the needed temperatures are very high (>400° C.).

The thin-film stack manufacturing apparatus disclosed in Japanese Patent Laid-Open No. 2008-176847 also requires a large chamber as a separate heater is provided in parallel to the targets.

### SUMMARY OF THE INVENTION

The present invention provides a magnetic recording medium manufacturing technique capable of sustaining the temperature of the substrate for the deposition of high anisotropy alloys by allowing uniform temperature control during deposition.

According to the first aspect of the present invention, there is provided a thin film formation apparatus which includes a plurality of chambers, and performs processing for forming thin films on two surfaces of a substrate transferred to the plurality of chambers, wherein a first sputtering chamber of the plurality of chambers includes a first sputtering film formation unit configured to perform a sputtering film formation process on a first surface of the substrate, and a first heating unit configured to heat a second surface opposite to the first surface of the substrate, and a second sputtering chamber of the plurality of chambers includes a second heating unit configured to heat the first surface of the substrate having undergone the sputtering film formation process performed by the first sputtering chamber, and a second sputtering film formation unit configured to perform a sputtering film formation process on the second surface of the substrate heated by the first sputtering chamber.

According to the second aspect of the present invention, there is provided a thin film formation apparatus which includes a plurality of chambers, and performs processing for forming thin films on two surfaces of a substrate transferred to the plurality of chambers, wherein a first sputtering chamber of the plurality of chambers includes a first target accommodating unit configured to accommodate a first target for performing a film formation process on a first surface of the substrate, a first heating unit formed to surround a periphery of the first target, and configured to heat the first surface of the substrate, a second heating unit configured to heat a second surface opposite to the first surface of the substrate, and a second target accommodating unit formed to surround a periphery of the second heating unit, and configured to accommodate a second target for performing a film formation process on the second surface of the substrate, and a second sputtering chamber of the plurality of chambers includes a third heating unit configured to heat the first surface of the substrate, a third target accommodating unit formed to surround a periphery of the third heating unit, and configured to accommodate a third target for performing a film formation process on the first surface, a fourth target accommodating unit configured to accommodate a fourth target for performing a film formation process on the second surface of the substrate, and a fourth heating unit formed to surround a periphery of the fourth target accommodating unit, and configured to heat the second surface of the substrate.

According to the third aspect of the present invention, there is provided a magnetic recording medium manufacturing method including a heating step of heating a substrate to a predetermined temperature, and a film formation step of forming a film on the substrate heated in the heating step, wherein the above thin film formation apparatus is used in the heating step and the film formation step.

Further features of the present invention will become apparent from the following description of exemplary embodiments with reference to the attached drawings.

### BRIEF DESCRIPTION OF THE DRAWINGS

FIG. 1 is an exemplary sectional view showing an example of a magnetic recording medium manufactured by a magnetic recording medium manufacturing method according to an embodiment of the present invention.

FIG. 2 is a view showing an example of a thin film formation apparatus (magnetic recording medium manufacturing apparatus) according to the embodiment of the present invention.

FIG. 3 is a view for explaining chambers of the thin film formation apparatus (magnetic recording medium manufacturing apparatus) according to the embodiment of the present invention.

FIG. 4 is a sectional view for explaining the chambers of the thin film formation apparatus (magnetic recording medium manufacturing apparatus) according to the embodiment of the present invention.

FIG. 5 is a flowchart for explaining the magnetic recording medium manufacturing method according to the embodiment of the present invention.

FIG. 6 is a view showing a modification of the thin film formation apparatus (magnetic recording medium manufacturing apparatus) shown in FIG. 2.

### DESCRIPTION OF THE EMBODIMENTS

Preferred embodiments of the present invention will exemplarily be explained in detail below with reference to the accompanying drawings. Note that constituent elements described in the embodiments are merely examples, and the technical scope of the present invention is determined by the scope of the appended claims and is not limited by the following individual embodiments.

First, a magnetic recording medium as an example of a thin-film stack manufactured by a magnetic recording medium manufacturing apparatus and magnetic recording medium manufacturing method according to an embodiment of the present invention will be explained. Note that in this specification, the term “magnetic recording medium” is not limited to a magnetic disk such as a hard disk or a floppy (registered trademark) disk using only magnetism when recording and reading information. For example, a “magnetic recording medium” includes a magnetooptical recording medium such as an MO (Magneto Optical) disk using both magnetism and light, or a thermally assisted recording medium using both magnetism and heat.

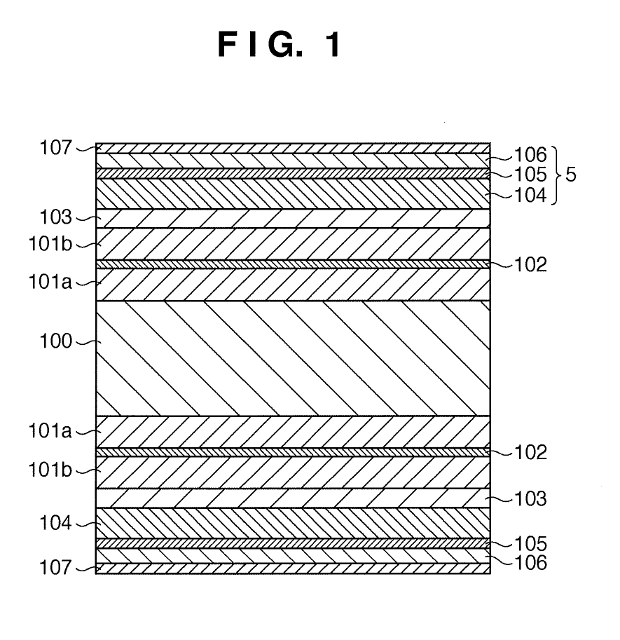

FIG. 1 is an exemplary sectional view showing an example of a magnetic recording medium (thin-film stack) manufactured by the magnetic recording medium manufacturing apparatus and magnetic recording medium manufacturing method according to the embodiment of the present invention. In this embodiment, an ECC (Exchange-Coupled Composite) medium obtained by improving a perpendicular recording medium will be explained as an example of the magnetic recording medium. However, the spirit and scope of the present invention are not limited to this example. For example, the magnetic recording medium may also be a general perpendicular recording medium, longitudinal recording medium, bit-patterned medium, or thermally assisted recording medium.

As shown in FIG. 1, the magnetic recording medium includes a substrate 100, and a first soft magnetic layers 101a, spacer layer 102, second soft magnetic layer 101b, seed layer 103, magnetic layer 104, exchange coupling control layer 105, third soft magnetic layer 106, and protective layer 107 sequentially stacked on one or both of the two surfaces of the substrate 100.

As the material of the substrate 100, it is possible to use a nonmagnetic material generally used as a magnetic recording medium substrate. Examples are glass, an Al alloy having a NiP plating film, ceramics, a flexible resin, and Si. In this embodiment, the substrate 100 is a disk-like member having a central hole. However, the present invention is not limited to this, and a rectangular member or the like may also be used.

The first soft magnetic layer 101a formed on the substrate 100 is a layer formed to improve the recording/reproduction characteristics by controlling the magnetic flux from a magnetic head for use in magnetic recording. However, the first soft magnetic layer 101a may also be omitted. As the constituent material of the first soft magnetic layer 101a, it is possible to use, e.g., CoZrNb, CoZrTa, or FeCoBCr in accordance with the film formed immediately above the first soft magnetic layer 101a.

As the material of the spacer layer 102, it is possible to use, e.g., Ru or Cr. The second soft magnetic layer 101b formed on the spacer layer 102 is identical to the first soft magnetic layer 101a. The first soft magnetic layer 101a, spacer layer 102, and second soft magnetic layer 101b form a soft underlayer.

The seed layer 103 formed on the soft underlayer is a layer formed immediately below the magnetic layer 104 in order to suitably control the crystal orientation, crystal grain size, grain size distribution, and grain boundary segregation of the magnetic layer 104. As the material of the seed layer 103, it is possible to use, e.g., MgO, Cr, Ru, Pt, or Pd.

A magnetic recording layer 5 includes the magnetic layer 104 having a large anisotropy Ku value, the exchange coupling control layer 105, and the third soft magnetic layer 106 having a small Ku value.

The magnetic layer 104 formed on the seed layer 103 and having a large Ku value affects the overall Ku value of the magnetic recording layer 5, so a material having a maximum possible Ku value is used. As the material of the magnetic layer 104, it is possible to use a material having an easy magnetization axis perpendicular to the substrate surface, and having a structure in which ferromagnetic grains are isolated by the nonmagnetic grain boundary component of an oxide. For example, it is possible to use a material obtained by adding an oxide to a ferromagnetic material containing at least CoPt. Examples are CoPtCr—SiO₂ and CoPt—SiO₂. It is also possible to use Co₅₀Pt₅₀, Fe₅₀Pt₅₀, or Co_{50-y}Fe_{y}Pt₅₀.

The exchange coupling control layer 105 formed on the magnetic layer 104 contains a crystalline metal or alloy, and an oxide. As the material of the crystalline metal or alloy, it is possible to use, e.g., Pt, Pd, or an alloy of Pt or Pd. As the crystalline alloy, it is also possible to use, e.g., an alloy of an element selected from Co, Ni, and Fe and a nonmagnetic metal.

The strength of the exchange coupling force between the magnetic layer 104 and third soft magnetic layer 106 can most simply be controlled by changing the film thickness of the exchange coupling control layer 105. The film thickness of the exchange coupling control layer 105 is, e.g., 0.1 to 2.0 nm.

The third soft magnetic layer 106 formed on the exchange coupling control layer 105 mainly functions to reduce the magnetization reversing magnetic field, so a material having a minimum possible Ku value is used. As the material of the third soft magnetic layer 106, it is possible to use, e.g., Co, NiFe, or CoNiFe.

The protective layer 107 formed on the third soft magnetic layer 106 is formed to prevent damage caused by the contact between a head and the medium surface. As the material of the protective layer 107, it is possible to use, e.g., a single component such as C, SiO₂, or ZrO₂, or a material obtained by adding an additive element to C, SiO₂, or ZrO₂ as a main component.

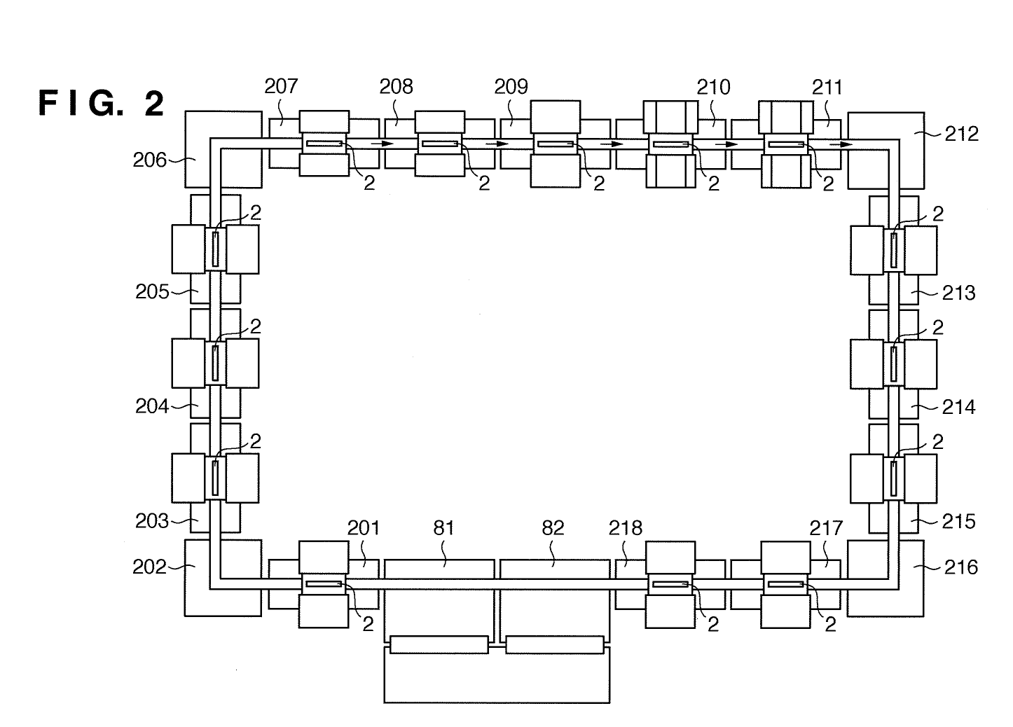

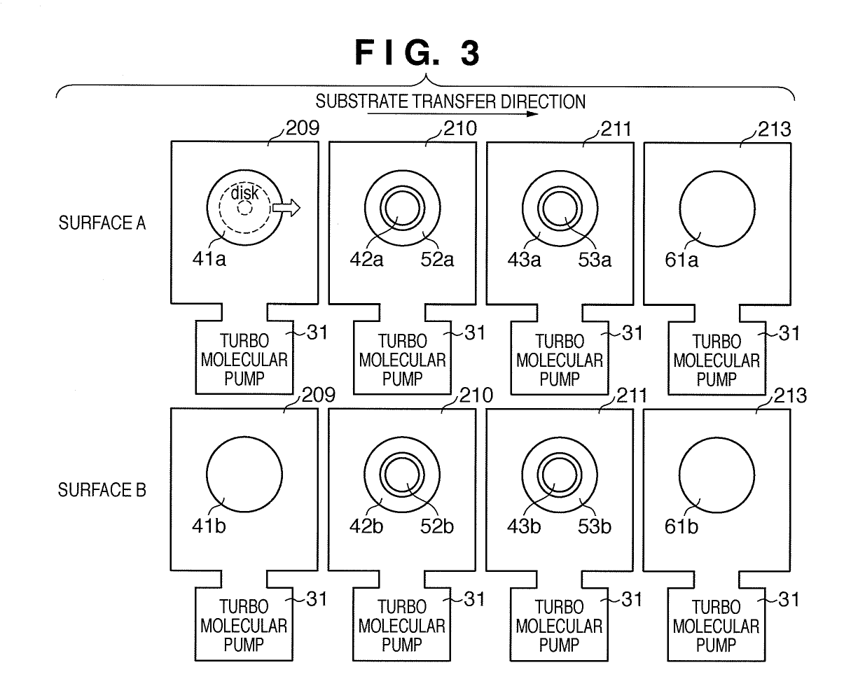

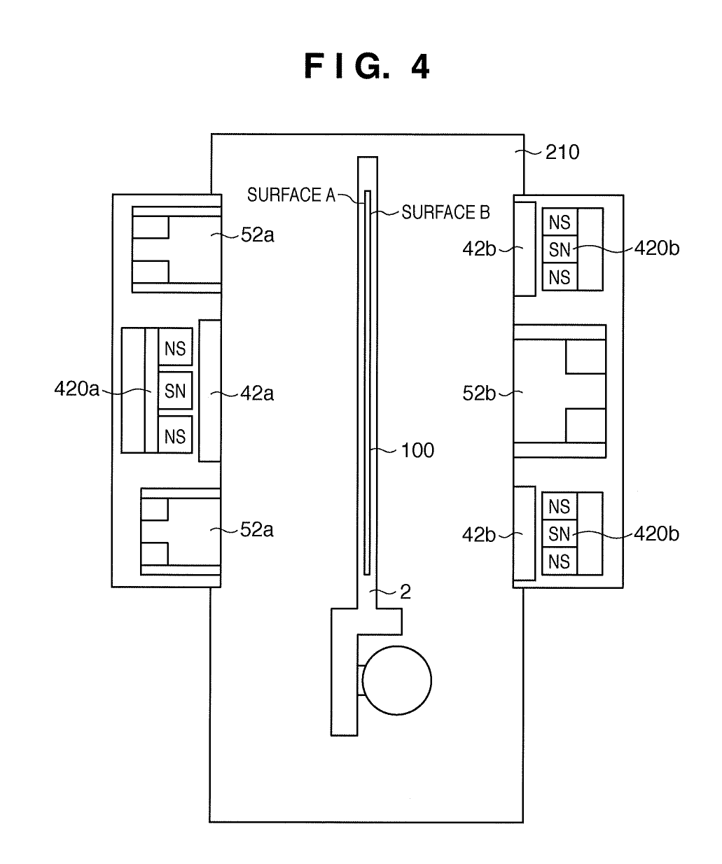

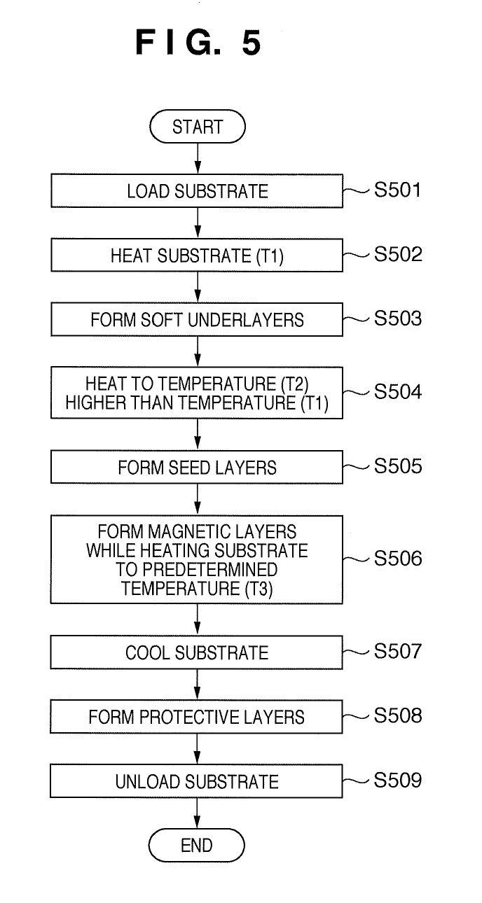

A thin-film formation apparatus (to be also referred to as a “magnetic recording medium manufacturing apparatus” hereinafter) used in the magnetic recording medium manufacturing method according to the embodiment of the present invention will be explained below. FIG. 2 is an exemplary view showing an example of the magnetic recording medium manufacturing apparatus according to the embodiment of the present invention. FIG. 3 is an exemplary view for explaining chambers 209, 210, 211, and 213 of the magnetic recording medium manufacturing apparatus. FIG. 4 is an exemplary sectional view for explaining the chamber 210 of the magnetic recording medium manufacturing apparatus. FIG. 5 is a flowchart for explaining the magnetic recording medium manufacturing method.

In the magnetic recording medium manufacturing apparatus as shown in FIG. 2, a load lock chamber 81 for loading the substrate 100 (FIG. 1) on a carrier 2, an unload lock chamber 82 for unloading the substrate 100 from the carrier 2, and a plurality of chambers 201, 202, 203, 204, 205, 206, 207, 208, 209, 210, 211, 212, 213, 214, 215, 216, 217, and 218 are arranged along the contours of a rectangle. Also, a transfer path is formed along the load lock chamber 81, chambers 201 to 218, and unload lock chamber 82. The transfer path has a plurality of carriers 2 capable of carrying the substrate 100. In each chamber, a processing time (tact time) required for the processing of the substrate 100 is predetermined. When this processing time (tact time) has elapsed, the substrates 100 carried by the carriers 2 are sequentially transferred to the next chambers.

For the magnetic recording medium manufacturing apparatus to process about 1,000 substrates per hour, the tact time in one chamber is about 5 sec or less, preferably, about 3.6 sec or less.

Each of the load lock chamber 81, unload lock chamber 82, and chambers 201, 202, 203, 204, 205, 206, 207, 208, 209, 210, 211, 212, 213, 214, 215, 216, 217, and 218 is a vacuum chamber that can be evacuated by a dedicated or shared evacuating system. Gate valves (not shown) are formed in the boundary portions between the load lock chamber 81, unload lock chamber 82, and chambers 201, 202, 203, 204, 205, 206, 207, 208, 209, 210, 211, 212, 213, 214, 215, 216, 217, and 218.

More specifically, the chamber 201 of the magnetic recording medium manufacturing apparatus is a chamber for forming the first soft magnetic layer 101a on the substrate 100. The direction change chamber 202 is a chamber for changing the transfer direction of the carrier 2. The chamber 203 is a chamber for forming the spacer layer 102 on the first soft magnetic layer 101a. The chamber 204 is a chamber for forming the second soft magnetic layer 101b on the spacer layer 102. The chamber 205 is a chamber for forming the seed layer 103 on the second soft magnetic layer 101b. The direction change chamber 206 is a chamber for changing the transfer direction of the carrier 2. The chamber 207 (a first heating chamber) and the chamber 208 (a second heating chamber) are preheating chambers for preheating the substrate 100. Note that the seed layer 103 can also be formed in the chamber 209.

The chambers 210 and 211 are chambers capable of functioning as sputtering modules for forming the magnetic layer 104 on the seed layer 103. The direction change chamber 212 is a chamber for changing the direction of the carrier 2. The cooling chamber 213 is a chamber for cooling the substrate 100. The chamber 214 is a chamber for forming the exchange coupling control layer 105 on the magnetic layer 104. The chamber 215 is a chamber for forming the third soft magnetic layer 106 on the exchange coupling control layer 105. The direction change chamber 216 is a chamber for changing the direction of the carrier 2. The chambers 217 and 218 are chambers for forming the protective layer 107.

FIG. 3 is a view for explaining details of the chamber 209 for forming the seed layer 103, the chambers 210 and 211 functioning as sputtering modules for forming the magnetic layer 104, and the cooling chamber 213 for cooling the substrate in the magnetic recording medium manufacturing apparatus shown in FIG. 2. Referring to FIG. 3, the arrow indicates the substrate transfer direction. Note that the direction change chamber 212 shown in FIG. 2 is not shown in FIG. 3, as it is not a chamber for processing the substrate.

Referring to FIG. 3, the front surface (first surface) of the substrate 100 is surface A, and the rear surface (second surface) of the substrate 100, which is opposite to (faces) surface A, is surface B. In the arrangement shown in FIG. 3, the substrate 100 is clamped from the edges. Referring to FIG. 3, “a” attached to each reference numeral indicates the arrangement on the surface A side, and “b” indicates that on the surface B side.

In the chamber 209 for forming the seed layer 103, targets 41a and 41b are installed to face each other. This makes it possible to form the seed layers 103 on the two surfaces of the substrate 100. As the target material for forming the seed layers 103, it is possible to use, e.g., Co₅₀Pt₅₀, Fe₅₀Pt₅₀, or Co_{50-y}Fe_{y}Pt₅₀. Note that a turbo molecular pump (to be referred to as a “TMP” hereinafter) 31 for evacuating a chamber is connected to each of the chambers 209, 210, 211, and 213.

Next, the chambers 210 and 211 functioning as sputtering modules for forming the magnetic layer 104 will be explained in detail below as the feature of the present invention.

The chamber 210 forms the magnetic layers 104 on the substrate by sputtering target materials set in the chamber 210.

On the first surface side (surface A side), the chamber 210 includes a first target accommodating unit (table) for accommodating a first target 42a for forming the magnetic layer 104 on the substrate, and a heating unit 52a (first heating unit) that is formed to surround the periphery of the first target and heats the substrate.

Also, on the second surface side (surface B side) opposite to the first surface side (surface A side), the chamber 210 includes a heating unit 52b (second heating unit) that is formed to face the first target accommodating unit and heats the substrate, and a second target accommodating unit (table) that is formed to surround the periphery of the heating-unit 52b (second heating unit), and accommodates a second target 42b for forming the magnetic layer 104 on the substrate.

The chamber 211 connected to the chamber 210 forms the magnetic layers 104 on the substrate by sputtering target materials set in the chamber 211.

On the first surface side (surface A side), the chamber 211 includes a heating unit 53a (third heating unit) for heating the substrate, and a third target accommodating unit (table) that is formed to surround the periphery of the heating unit 53a (third heating unit), and accommodates a third target 43a for forming the magnetic layer 104 on the substrate.

Also, on the second surface side (surface B side) opposite to the first surface side (surface A side), the chamber 211 includes a fourth target accommodating unit (table) that is formed to face the heating unit 53a (third heating unit), and accommodates a fourth target 43b for forming the magnetic layer 104 on the substrate, and a heating unit 53b (fourth heating unit) that is formed to surround the periphery of the fourth target accommodating unit (table), and heats the substrate.

The first target 42a and the fourth target 43b are formed to have almost identical disk shapes, and the heating unit 52a (first heating unit) and the heating unit 53b (fourth heating unit) are formed to have almost identical ring shapes.

The second target 42b and the third target 43a are formed to have almost identical ring shapes, and the heating unit 52b (second heating unit) and the heating unit 53a (third heating unit) are formed to have almost identical disk shapes.

The heating unit 52a (first heating unit) heats a region corresponding to the third target accommodating unit accommodating the third target 43a. The heating unit 52b (second heating unit) heats a region corresponding to the fourth target accommodating unit accommodating the fourth target 43b.

The heating unit 53a (third heating unit) heats a region corresponding to the first target accommodating unit accommodating the first target 42a. The heating unit 53b (fourth heating unit) heats a region corresponding to the second target accommodating unit accommodating the second target 42b.

In the chamber 210, the heating unit 52a is placed in a position where it primarily heats the outer periphery of the substrate, and the heating unit 52b is placed in a position where it mainly heats the central portion of the substrate. The entire substrate can be heated by thus arranging the heating units 52a and 52b. This makes it possible to raise or maintain the temperature of the substrate and its uniformity while depositing the magnetic alloys.

Also, in the chamber 211, the heating unit 53b is placed in a position where it heats the outer periphery of the substrate, and the heating unit 53a is placed in a position where it heats the central portion of the substrate. By thus arranging the heating units 53a and 53b, the entire substrate can be heated from portions different from the portions heated in the chamber 210. This makes it possible to perform uniform temperature control on the substrate surfaces while performing magnetic layer deposition.

In the two chambers 210 and 211, the magnetic layer 104 having a uniform film thickness can be formed on surface A of the substrate by sputtering from the first target 42a having a small diameter and the ring-like third target 43a having a larger diameter. Likewise, the magnetic layer 104 having a uniform film thickness can be formed on surface B of the substrate by sputtering from the fourth target 43b having a small diameter and the ring-like second target 42b having a larger diameter. Sputtering from the smaller target results in a thicker film near the middle of the substrate whereas sputtering from the larger annular target results in a film that is thicker near the substrate outer diameter. By judiciously adjusting the rates, a uniform magnetic film is formed on the entire substrate on both faces.

Note that as the “heating unit” herein mentioned, it is possible to use, e.g., a heater, block heater, or lamp heater. The efficiency of a lamp heater would be affected by deposition. Thus, a block heater may provide more repeatable temperatures even with deposition on its surface.

The above-mentioned magnetic layer material can be used as the first target 42a, third target 42b, second target 43a, and fourth target 43b. For example, it is possible to use a material obtained by adding an oxide to a ferromagnetic material containing at least CoPt. Examples are CoPtCr—SiO₂ and CoPt—SiO₂. It is also possible to use Co₅₀Pt₅₀, Fe₅₀Pt₅₀, or Co_{50-y}Fe_{y}Pt₅₀.

FIG. 4 is a schematic sectional view showing the chamber 210 in the substrate transfer direction (the substrate transfer direction is perpendicular to the drawing surface). The surface of the first target 42a which faces the substrate and the surface of the heating unit 52b (second heating unit) which faces the substrate are arranged in positions that are almost symmetrical with respect to the substrate. Similarly, the surface of the first heating unit 52a which faces the substrate and the surface of the second target 42b which faces the substrate are arranged in positions almost symmetrical with respect to the substrate. Note that a magnet unit 420a is installed at the back of the first target 42a, and a magnet unit 420b is installed at the back of the second target 42b.

In the chamber 210, the magnet unit 420a functions as a first sputtering unit for executing sputtering by generating magnetic fields while the target is held at a predetermined voltage. The magnet unit 420b functions as a second sputtering unit for executing sputtering by generating magnetic fields while the target is held a predetermined voltage. A magnet unit is installed at the back of the third target 43a in the chamber 211 as well. This magnet unit functions as a third sputtering unit for executing sputtering by generating magnetic fields while the target is held at a predetermined voltage. In addition, a magnet unit is installed at the back of the fourth target 43b. This magnet unit functions as a fourth sputtering unit for executing sputtering by generating magnetic fields while the target is held at a predetermined voltage.

The surfaces of the first target 42a and heating unit 52a which face the substrate are parallel but not necessarily on the same plane. Likewise, the surfaces of the second target 42b and heating unit 52b which face the substrate are parallel but not necessarily on the same plane.

For the magnetic recording medium manufacturing apparatus to process about 1,000 substrates per hour, the tact time in one chamber must be shortened to about 5 sec or less, desirably, about 3.6 sec or less as described previously. To achieve a heating process (temperature control) for heating the substrate to a desired temperature (about 400° C. to 600° C.) while the tact time is thus limited, the surfaces of the heating units 52a and 52b are arranged at a distance of, e.g., 50 mm or less, preferably, 30 mm or less from the substrate surface.

Referring to FIG. 3 again, the cooling chamber 213 includes cooling mechanisms 61a and 61b facing each other, in order to cool the two surfaces of the substrate on which the magnetic layers 104 are formed. The two surfaces of the substrate, having the magnetic layers 104 formed while heating to a desired temperature in the chambers 210 and 211, are cooled by the cooling mechanism 61a (first cooling mechanism) and cooling mechanism 61b (second cooling mechanism) in the cooling chamber 213. The cooling process is needed to obtain the optimum temperature for later deposition of the protective layers 107, e.g., to about 200° C. or less.

As explained above, this embodiment can provide a magnetic recording medium manufacturing apparatus (sputtering apparatus) capable of maintaining or raising the substrate temperature during high anisotropy layer deposition as well as achieving temperature uniformity on the substrate.

Next, a magnetic recording medium manufacturing method using the magnetic recording medium manufacturing apparatus according to the embodiment of the present invention will be explained below with reference to FIGS. 1 and 5.

In step S501, a substrate is carried into the load lock chamber 81, and loaded as it is placed on the carrier 2 by a substrate transfer robot (not shown).

In step S502, the substrate is heated to a predetermined temperature T1 (about 100° C.) in the load lock chamber 81, thereby removing contaminants and water sticking to the substrate.

In step S503, soft underlayers are formed. More specifically, first soft magnetic layers 101a are formed in the chamber 201, spacer layers 102 (the thickness is 0.7 to 2 nm) are formed in the chamber 203, and second soft magnetic layers 101b are formed in the chamber 204.

In step S504, the substrate is sequentially transferred to the chamber 207 (first heating chamber) and chamber 208 (second heating chamber), and heated to a temperature T2 (about 400° C. to 700° C.) higher than the temperature T1 (about 100° C.) in step S502. This step is in preparation for achieving magnetic layers 104 of high magnetic anisotropy. In the magnetic recording medium manufacturing apparatus, the processing time (tact time) in one chamber is limited in order to increase the throughput. In the chambers 210 and 211 for forming magnetic layers 104, it is difficult to heat the substrate to a temperature required to increase the magnetic anisotropy of magnetic layers 104 within the limited time. Therefore, the magnetic recording medium manufacturing apparatus includes the chamber 207 (first heating chamber) and chamber 208 (second heating chamber) for preheating (preliminary heating). In the magnetic recording medium manufacturing apparatus, the chamber 207 (first heating chamber) and the chamber 208 (second heating chamber) function as preliminary heating units.

Since the substrate temperature decreases before the substrate is transferred to the chamber 210 for forming magnetic layers 104, the substrate must be heated (preliminarily heated) in the chamber 207 (first heating chamber) and chamber 208 (second heating chamber) to a temperature equal to or higher than the temperature required to increase the magnetic anisotropy in the chamber 210. If the substrate made of glass is overheated, however, it may plastically deform rendering it useless as a rigid disk medium. Moreover, it could fall from the carrier 2 and adversely affect the operation of the entire tool. In the chamber 207 (first heating chamber) and chamber 208 (second heating chamber), therefore, the glass substrate is heated to a temperature below the plastic deformation temperature.

In step S505, seed layers 103 are formed to suitably control the crystal characteristics of magnetic layers 104. Note that the seed layers 103 may also be formed in the chamber 205 before the heating step in step S504.

In step S506, the substrate is transferred to the chambers 210 and 211 for forming magnetic layers 104, and magnetic layers 104 are formed while the substrate is heated to a predetermined temperature T3 (about 400° C. to 600° C.). In this step, the magnetic layers 104 are formed while the substrate is uniformly heated in the chamber 210 as described previously.

In step S507, the substrates are sequentially transferred to the cooling chamber 213 and cooled to a temperature optimum for the formation of protective layers 107. When using carbon as the material of the protective layers 107, the substrate must be cooled to, e.g., about 200° C. or less.

Subsequently, in step S508, the substrate is transferred to the chambers 217 and 218 for CVD, where the protective layers 107 may be formed.

Note that ultra-thin exchange coupling control layers 105 may also be formed between the magnetic layers 104 and protective layers 107 in the chamber 214. Note also that third soft magnetic layers 106 may also be formed in the chamber 215 after the substrate is cooled and before the protective layers 107 are formed.

In step S509, the substrate is unloaded as it is removed from the carrier 2 in the unload lock chamber 82.

As explained above, this embodiment can provide a magnetic recording medium manufacturing method capable of performing temperature control on substrate surfaces.

(Modification)

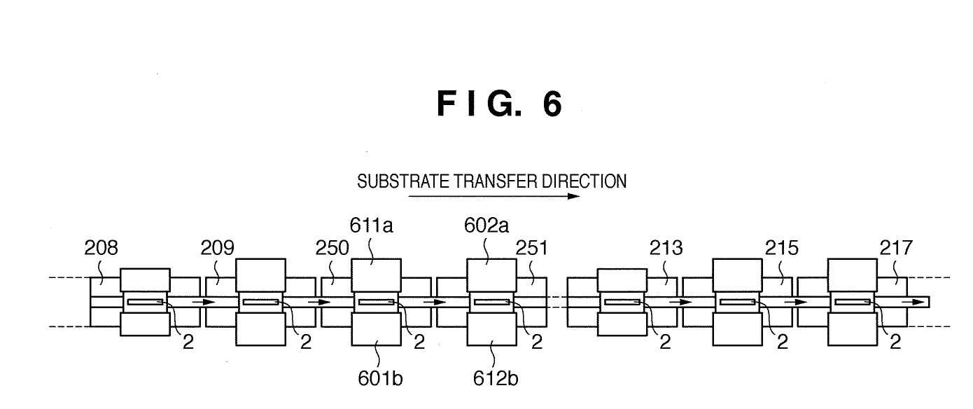

FIG. 6 is a view showing a modification of the arrangement of the thin film formation apparatus (magnetic recording medium manufacturing apparatus) shown in FIG. 2. The magnetic recording medium manufacturing apparatus shown in FIG. 6 includes chambers 250 and 251 instead of the chambers 210 and 211 shown in FIG. 2. Note that the same reference numerals as in FIG. 2 denote the same parts, and a repetitive explanation will be omitted. Note also that in the magnetic recording medium manufacturing apparatus shown in FIG. 6, a load lock chamber 81, chambers 201 to 207, 212, 214, 216, and 218, and an unload lock chamber 82 are not shown for the sake of illustrative simplicity.

As shown in FIG. 6, the chamber 250 includes a heating unit 611a installed on the surface B side of a substrate, and a sputtering film formation unit (first sputtering film formation unit) installed on the surface A side of the substrate and including a target 601b and magnet unit (not shown) for performing a sputtering film formation process. When processing surface B (a second surface) of the substrate in the chamber 250, the heating unit 611a heats the substrate from surface A (a first surface) of the substrate, which is opposite to surface B. In this arrangement, a sputtering film formation process can be performed while the substrate is uniformly heated.

The chamber 250 functions as a first sputtering chamber, and connects to the chamber 251 functioning as a second sputtering chamber.

The chamber 251 includes a heating unit 612b installed on the surface A side of the substrate, and a sputtering film formation unit (second sputtering film formation unit) installed on the surface B side of the substrate and including a target 602a and magnet unit (not shown) for performing a sputtering film formation process. When processing surface A (the first surface) of the substrate in the chamber 251, the heating unit 612b heats the substrate from its surface B (the second surface), which is opposite to surface A. In this arrangement, a sputtering film formation process can be performed while the substrate surface that is not heated in the chamber 250 is uniformly heated in the chamber 251.

When forming magnetic recording layers having magnetic anisotropy, the magnetic recording medium manufacturing apparatus shown in FIG. 6 can perform a sputtering film formation process while uniformly heating the substrate surfaces with a simpler arrangement.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-282384 filed on Oct. 31, 2008, which is hereby incorporated by reference herein in its entirety.

What is claimed is:

1. A thin film formation apparatus which includes a plurality of chambers, and performs processing for forming thin films on two surfaces of a substrate transferred to the plurality of chambers, wherein
a first sputtering chamber of the plurality of chambers includes:
a first sputtering film formation unit configured to perform a sputtering film formation process on a first surface of the substrate, and
a first heating unit configured to heat a second surface opposite to the first surface of the substrate, and
a second sputtering chamber of the plurality of chambers includes:
a second heating unit configured to heat the first surface of the substrate having undergone the sputtering film formation process performed by said first sputtering chamber, and
a second sputtering film formation unit configured to perform a sputtering film formation process on the second surface of the substrate heated by said first sputtering chamber.

2. A thin film formation apparatus which includes a plurality of chambers, and performs processing for forming thin films on two surfaces of a substrate transferred to the plurality of chambers, wherein
a first sputtering chamber of the plurality of chambers includes:
a first target accommodating unit configured to accommodate a first target for performing a film formation process on a first surface of the substrate,
a first heating unit formed to surround a periphery of said first target, and configured to heat the first surface of the substrate,
a second heating unit configured to heat a second surface opposite to the first surface of the substrate, and
a second target accommodating unit formed to surround a periphery of said second heating unit, and configured to accommodate a second target for performing a film formation process on the second surface of the substrate, and
a second sputtering chamber of the plurality of chambers includes:
a third heating unit configured to heat the first surface of the substrate,
a third target accommodating unit formed to surround a periphery of said third heating unit, and configured to accommodate a third target for performing a film formation process on the first surface,
a fourth target accommodating unit configured to accommodate a fourth target for performing a film formation process on the second surface of the substrate, and
a fourth heating unit formed to surround a periphery of said fourth target accommodating unit, and configured to heat the second surface of the substrate.

3. The apparatus according to claim 2, wherein
said first heating unit heats a region of the substrate, which faces said third target accommodating unit,
said second heating unit heats a region of the substrate, which faces said fourth target accommodating unit,
said third heating unit heats a region of the substrate, which faces said first target accommodating unit, and
said fourth heating unit heats a region of the substrate, which faces said second target accommodating unit.

4. A magnetic recording medium manufacturing method comprising:
a heating step of heating a substrate to a predetermined temperature; and
a film formation step of forming a film on the substrate heated in the heating step,
wherein a thin film formation apparatus according to claim 1 is used in the heating step and the film formation step.

5. A magnetic recording medium manufacturing method comprising:
a heating step of heating a substrate to a predetermined temperature; and
a film formation step of forming a film on the substrate heated in the heating step,
wherein a thin film formation apparatus according to claim 2 is used in the heating step and the film formation step.
